(19) United States
(12) Patent Application Publication
(10) Pub. No.: US 2014/0014521 A1
(43) Pub. Date: Jan. 16, 2014

(54) FLEXIBLE CIRCUIT BOARD AND METHOD FOR MANUFACTURING SAME

(71) Applicant: ARAKAWA CHEMICAL INDUSTRIES, LTD., Osaka (JP)

(72) Inventors: Akihisa HAMAZAWA, Osaka-shi (JP); Koji Nishimura, Osaka-shi (JP); Hideki Goda, Osaka-shi (JP)

(73) Assignee: ARAKAWA CHEMICAL INDUSTRIES, LTD., Osaka (JP)

(21) Appl. No.: 14/029,637

(22) Filed: Sep. 17, 2013

Related U.S. Application Data
(62) Division of application No. 13/265,042, filed on Oct. 18, 2011.

(30) Foreign Application Priority Data
May 26, 2009 (JP) 2009-126882

(51) Int. Cl. H05K 1/02

(52) U.S. Cl. CPC H05K 1/0277
USPC 205/125

(57) ABSTRACT

An object of the present invention is to provide a flexible circuit board that maintains high insulation reliability, exhibits high wiring adhesion, has low thermal expansion, and allows the formation of a fine circuit thereon. Specifically, the present invention provides a flexible circuit board, wherein at least a nickel plating layer is laminated on a polyimide film to form a polyimide film provided with a nickel plating layer and a wiring pattern is applied to the nickel plating layer thereof. The polyimide film has a thermal expansion coefficient of 0 to 8 ppm/° C. in the temperature range from 100 to 200° C., and the nickel plating layer has a thickness of 0.03 to 0.3 μm.

### TECHNICAL FIELD

The present invention relates to a flexible circuit board and a method for producing the same. Specifically, the invention relates to a flexible circuit board that can be obtained by a semi-additive process, wherein a seed layer is formed on an insulation film by wet plating and then a wiring pattern is formed by plating.

### BACKGROUND ART

There is an increasing demand for flexible printed circuits (hereunder referred to as “FPC”) in response to the recent trends toward reducing the weight and size, and increasing the packaging density of electronic products. Generally, an FPC has a structure wherein a circuit formed of metal foil is provided on an insulation film via an adhesive.

A polyimide film and the like are preferably used as the insulation film described above, and epoxy based, acrylic based and like thermosetting adhesives are generally used as the adhesive (an FPC using such a thermosetting adhesive is also referred to as a “triple-layer FPC”). The thermosetting adhesive is advantageous in that it allows adhesion even at a relatively low temperature. However, it is predictable that there will be stricter requirements in the future in terms of heat resistance, flexibility, electrical reliability, and the like. It is suspected that conventional triple-layer FPCs using a thermosetting adhesive will not be able to easily meet such requirements.

In response to this predictable problem, an FPC having a metal layer directly provided on an insulation film, or an FPC using a thermoplastic polyimide as the adhesive layer (hereunder referred to as a “double-layer FPC”) is currently being studied. Double-layer FPCs have characteristics that are superior to those of triple-layer FPCs; therefore, there will be an increasing demand for the double-layer FPCs. The metal-clad laminate used in a double-layer FPC can be produced by the following methods: a cast method in which polyamic acid, which is a precursor of polyimide, is cast or applied to the surface of a metal foil and then the polyamic acid is imidized; a metallizing method in which a metal layer is directly provided on the polyimide film by sputtering or plating; or a lamination method in which a polyimide film is attached to a metal foil by using thermoplastic polyimide.

It is assumed that circuit miniaturization will further proceed in response to the trends toward reducing the weight and size, and increasing the packaging density of electronic products. Not only studying and developing suitable materials but also establishing methods for forming fine circuits is believed to be an important object.

The method most widely employed at the current time in forming circuits is that wherein a portion of the metal foil layer is removed from the metal-clad laminate by etching to form a circuit (i.e., a subtractive process). The subtractive process is a simple method by which a circuit can be obtained by simply etching a metal-clad laminate. However, because the etching proceeds radially rather than linearly, the cross section of the resulting circuit undesirably becomes a trapezoidal shape. This makes it difficult to form fine circuits having narrow line/space patterns.

Specifically, when the upper base of the circuit is adjusted according to the design values, the lower base of the adjacent circuit may be partially connected thereto, reducing the electrical reliability. Conversely, when the lower base of the circuit is adjusted according to the design values, the upper base may become extremely narrow, causing poor connections when mounting semiconductors. Due to these circumstances, a semi-additive process is now attracting attention as a method for forming fine circuits in place of the subtractive process.

The semi-additive process is generally performed in the following manner. First, a resist layer is formed on the surface of an insulation layer via an extremely thin underlying metal layer. Subsequently, the resist film is removed by a photographic or like method in the portion where a circuit is to be formed. The portion in which the underlying metal layer is exposed functions as a power supply electrode and electroplating is performed thereon to obtain a metal layer. Thereafter, the resist layer and unnecessary portion of the underlying metal layer are removed by etching. Circuits produced by the semi-additive process have an almost rectangular cross section. This solves the above-mentioned problems observed in the subtractive process and makes it possible to produce fine circuits in a high-precision manner.

The substrate used in a semi-additive process has a structure in which an underlying metal layer is provided on an insulation layer; therefore, either the cast method, metallizing method, or lamination method described above can be employed in its production. Among these, the metallizing method is most suitable as it can easily make the metal layer thinner. However, in the metallizing method, even when a metal layer is provided directly on the insulation layer, satisfactory adhesive strength cannot be obtained. In the semi-additive process, a circuit is formed on an underlying metal layer by electroplating; therefore, the adhesive strength of the circuit is greatly affected by the adhesive strength between the underlying metal layer and the insulation layer. Therefore, in this method, the use of multilayer substrate having an extremely thin metal layer firmly adhered to the insulation layer is required.

Considering the above, several methods, including an alkali treatment (PTL 1) and a surface roughening treatment (PTL 2), have been proposed. However, when the alkali treatment or surface roughening treatment is performed, the number of production steps increases and the production process becomes undesirably complicated.

The cast method and lamination method are excellent for obtaining a metal-clad laminate having high adhesiveness between the insulation layer and the metal layer. In order to form an underlying metal layer for use in the semi-additive process, it is necessary to use an extremely thin metal foil. However, an extremely thin metal foil has poor self-supporting properties; therefore, it is difficult to pass such a thin metal foil through a cast or lamination line. In order to solve this problem, the following steps are proposed for the cast method. A copper film is first formed on the insulator by plating. A polyimide precursor is applied to the surface of the copper film and then imidized, followed by peeling the insulator (see PTL 3). However, in this method, when the insulator is peeled as the last step, a portion of the copper film remains on the surface of the insulator. This may make it impossible to obtain a uniform, extremely thin metal-clad laminate in a continuous manner.

Although it is applicable to a subtractive process and not to a semi-additive process, a method for producing a multilayer substrate has been proposed as described below. Namely, in the lamination method, a copper foil provided with a release layer is used and the release layer is removed after the completion of the lamination (see PTL 4). In this case, it seems that no problems are evident because the lamination is performed at a temperature less than 300° C. However, when a polyimide-based adhesive is used as the adhesive in order to obtain a multilayer substrate having high heat resistance, it is necessary to use a high temperature to perform lamination. This may cause wrinkles and other appearance problems due to thermal strain that occurs during lamination. In particular, a copper foil provided with a release layer is designed to weaken the adhesive strength at the interface between the release layer and the copper foil. Therefore, if wrinkles and the like occur, the distortion tends to concentrate at the interface and cause peeling, making continuous lamination difficult.

### CITATION LIST

### Patent Literature

PTL 1: Japanese Unexamined Patent Publication No. 1993-90737

PTL 2: Japanese Unexamined Patent Publication No. 1994-210795

PTL 3: Japanese Unexamined Patent Publication No. 1994-198804

PTL 4: Japanese Examined Patent Publication No. 2002-316386

### SUMMARY OF INVENTION

### Technical Problem

In order to solve the above-described problems, an object of the present invention is to provide a flexible circuit board that maintains high insulation reliability, exhibits high wiring adhesion, has low thermal expansion and allows the formation of a fine circuit thereon, and a production method thereof.

### Solution to Problem

As a result of extensive research, the present inventors found that the above object can be achieved by using a polyimide film provided with an electroless nickel plating layer that can be obtained by performing electroless wet nickel plating on a polyimide film having a specific coefficient of thermal expansion.

The present invention relates to the following flexible circuit boards and production methods thereof.

Item 1. A flexible circuit board comprising a wiring pattern formed on a nickel plating layer of a polyimide film provided with a nickel plating layer that is obtained by laminating at least a nickel plating layer on a polyimide film,

the polyimide film having a coefficient of thermal expansion of 0 to 8 ppm/° C. in the temperature range from 100 to 200° C., and the nickel plating layer having a thickness of 0.03 to 0.3 μm.

Item 2. The flexible circuit board according to Item 1, wherein the nickel plating layer has a thickness of 0.1 to 0.3 μm.

Item 3. The flexible circuit board according to Item 1, which is obtained by a process comprising:

a first step of subjecting polyimide film (1) having a coefficient of thermal expansion of 0 to 8 ppm/° C. in the temperature range from 100 to 200° C. to at least electroless nickel plating to form a polyimide film provided with a nickel plating layer, wherein the nickel plating layer has a thickness of 0.03 to 0.3 μm,

a second step of forming a resist layer for pattern electrolytic copper plating by disposing a dry film resist layer on the polyimide film provided with the nickel plating layer obtained in the first step, and performing exposure and development,

a third step of forming an electrically conductive layer into a pattern by performing electrolytic copper plating on the polyimide film provided with a resist layer for pattern electrolytic copper plating obtained, and

a fourth step of selectively etching, after removing the resist layer for pattern electrolytic copper plating, the electroless nickel plating layer in the portion where the electrolytic copper plating layer is not provided.

Item 4. A method for producing the flexible circuit board of Item 1 comprising:

a first step of subjecting polyimide film (1) having a coefficient of thermal expansion of 0 to 8 ppm/° C. in the temperature range from 100 to 200° C. to at least electroless nickel plating to form a polyimide film provided with a nickel plating layer, wherein the nickel plating layer has a thickness of 0.03 to 0.3 μm,

a second step of forming a resist layer for pattern electrolytic copper plating by disposing a dry film resist layer on the polyimide film provided with the nickel plating layer obtained in the first step, and performing exposure and development,

a third step of forming an electrically conductive layer into a pattern by performing electrolytic copper plating on the polyimide film provided with a resist layer for pattern electrolytic copper plating obtained, and

a fourth step of selectively etching, after removing the resist layer for pattern electrolytic copper plating, the electroless nickel plating layer in the portion where the electrolytic copper plating layer is not provided.

Item 5. The method for producing a flexible circuit board according to Item 4, which further comprises forming a through hole and/or nonthrough hole in the polyimide film (1) before performing the electroless nickel plating in the first step.

Item 6. The method for producing a flexible circuit board according to Item 4 or 5, wherein the polyimide film (1) is a block copolymerized polyimide/silica hybrid film obtained by heat curing an alkoxy-containing silane modified block copolymerized polyamic acid (b).

Item 7. The method for producing a flexible circuit board according to any one of Items 4 to 6, wherein, in the second step, the resist layer for pattern electrolytic copper plating is formed using a dry film resist, and, in the third step, the patterned copper circuit that is formed by electrolytic copper plating has a width of 4 to 18 μm.

Item 8. The method for producing a flexible circuit board according to any one of Items 4 to 7, wherein, in the second step, the resist layer for pattern electrolytic copper plating is formed using a dry film resist, and, in the third step, the patterned copper circuit that is formed by electrolytic copper plating has a height of 2 to 20 μm.

Item 9. The method for producing a flexible circuit board according to any one of Items 4 to 8, wherein a selective etching solution having an etching rate for copper of 0.2 μm/min or lower and an etching rate for electroless nickel plating layer of 1.0 μm/min or higher is used in the selective etching performed in the fourth step.

Item 10. The method for producing the flexible circuit board according to any one of Items 4 to 9, wherein an electroless copper plating layer is further formed on the electroless nickel plating layer in the first step.

### Advantageous Effects of Invention

In the present invention, an electroless nickel plating layer with a thickness of 0.03 to 0.3 μm is directly laminated on a polyimide film having a low coefficient of thermal expansion. This makes it possible to provide a flexible circuit board that maintains high insulation reliability, exhibits high wiring adhesion, has low thermal expansion, and allows the formation of a fine circuit. The flexible circuit board of the present invention is excellent in thermal stability and dimensional stability. Furthermore, the method for producing the flexible circuit board of the present invention allows a high-definition electrically conductive circuit to be produced in a simple manner.

### DESCRIPTION OF EMBODIMENTS

The present invention relates to a flexible circuit board comprising a wiring pattern formed on a nickel plating layer of a polyimide film provided with a nickel plating layer that is obtained by laminating at least a nickel plating layer on a polyimide film, wherein the polyimide film has a coefficient of thermal expansion of 0 to 8 ppm/° C. in the temperature range from 100 to 200° C., and the nickel plating layer has a thickness of 0.03 to 0.3 μm.

The flexible circuit board of the present invention is produced by the following steps:

a first step of subjecting polyimide film (1) having a coefficient of thermal expansion of 0 to 8 ppm/° C. in the temperature range from 100 to 200° C. to at least electroless nickel plating to form a polyimide film provided with a nickel plating layer, wherein the nickel plating layer has a thickness of 0.03 to 0.3 μm,

a second step of forming a resist layer for pattern electrolytic copper plating by disposing a dry film resist layer on the polyimide film provided with a nickel plating layer, and performing exposure and development,

a third step of forming an electrically conductive layer into a pattern by performing electrolytic copper plating on the polyimide film provided with a resist layer for pattern electrolytic copper plating, and

a fourth step of selectively etching, after removing the resist layer for pattern electrolytic copper plating, the electroless nickel plating layer in the portion where the electrolytic copper plating layer is not provided.

There are no limitations on the polyimide film (1) used in the present invention as long as it is a non-thermoplastic polyimide film having a coefficient of thermal expansion of 0 to 8 ppm/° C. in the temperature range from 100 to 200° C., and conventionally known polyimide films can be used as they are. If the coefficient of thermal expansion exceeds 8 ppm/° C., formation of a fine circuit cannot be achieved due to thermal expansion occurring during the substrate production, thus this is not preferable. Here, the coefficient of thermal expansion means the value (ratio of expansion and contraction)/(temperature) within the range of 100 to 200° C., which is measured using a thermomechanical analyzer under the following tensile mode (distance between chucks: 20 mm, width of test piece: 4 mm, load: 10 mg, and temperature rise rate: 10° C./min).

Such polyimide films can be produced by the methods disclosed in, for example, Japanese Unexamined Patent Publication No. 1993-70590, Japanese Unexamined Patent Publication No. 2000-119419, Japanese Unexamined Patent Publication No. 2007-56198, Japanese Unexamined Patent Publication No. 2005-68408, and the like. Commercially available polyimide films may also be used. Examples of commercially available polyimide films include XENOMAX (tradename) produced by Toyobo Co., Ltd., and Pomiran T (tradename) produced by Arakawa Chemical Industries, Ltd.

Among these polyimide films, block copolymerized polyimide/silica hybrid films are preferable because they have excellent adhesion to electroless nickel plating and satisfactory dimensional stability. The block copolymerized polyimide/silica hybrid film may be produced by the method described below or commercially available film may be used. Pomiran T (tradename) produced by Arakawa Chemical Industries, Ltd. is the most preferable among the commercially available block copolymerized polyimide/silica hybrid films.

The block copolymerized polyimide/silica hybrid film can be produced, for example, by heat-curing alkoxy-containing silane modified block copolymerized polyamic acid according to the method disclosed in Japanese Unexamined Patent Publication No. 2005-68408. The alkoxy-containing silane modified block copolymerized polyamic acid (b) (hereunder referred to as component (b)) can be obtained by:

reacting tetracarboxylic dianhydride with a diamine compound to obtain polyamic acid (1); reacting the resulting polyamic acid (1) with epoxy-containing alkoxysilane partial condensate to obtain polyamic acid (a) (hereunder referred to as component (a)); reacting tetracarboxylic dianhydride with a diamine compound to obtain polyamic acid (2); and mixing and condensing component (a) with the polyamic acid (2). The component (a) segment has the alkoxysilane partial condensate in the side chain, and forms silica by a sol-gel reaction. The polyamic acid (2) segment does not contain silica, and contributes to the development of high elastic modulus and low thermal expansion in the block copolymerized polyimide/silica hybrid film.

At this time, in terms of the tetracarboxylic dianhydrides and diamine compounds that constitute polyamic acid (1) and polyamic acid (2), various conventionally known ones can be used as long as their amounts and types are selected so that the polyimide film has a coefficient of thermal expansion of 0 to 8 ppm/° C. in the temperature range from 100 to 200° C.

Examples of tetracarboxylic dianhydrides used for the preparation of polyamic acid (1) and polyamic acid (2) include pyromellitic dianhydride, 1,2,3,4-benzenetetracarboxylic dianhydride, 1,4,5,8-naphthalenetetracarboxylic dianhydride, 2,3,6,7-naphthalenetetracarboxylic dianhydride, 1,2,5,6-naphthalenetetracarboxylic dianhydride, 3,3′,4,4′-biphenyltetracarboxylic dianhydride, 2,2′,3,3′-biphenyltetracarboxylic dianhydride, 2,3,3′,4′-biphenyltetracarboxylic dianhydride, 3,3′,4,4′-benzophenonetetracarboxylic dianhydride, 2,3,3′,4′-benzophenonetetracarboxylic dianhydride, 3,3′,4,4′-diphenylethertetracarboxylic dianhydride, 2,3,3′,4′-diphenylethertetracarboxylic dianhydride, 3,3′,4,4′-diphenylsulfonetetracarboxylic dianhydride, 2,3,3′,4′-diphenylsulfonetetracarboxylic dianhydride, 2,2-bis(3,3′,4,4′-tetracarboxyphenyl)tetrafluoropropane dianhydride, 2,2′-bis(3,4-dicarboxyphenoxyphenyl)sulfone dianhydride, 2,2-bis(2,3-dicarboxyphenyl)propane dianhydride, 2,2-bis(3,4-dicarboxyphenyl)propane dianhydride, cyclopentanetetracarboxylic dianhydride, butane-1,2,3,4-tetracarboxylic dianhydride, and 2,3,5-tricarboxycyclopentylacetic dianhydride.

Examples of diamine compounds used for the preparation of polyamic acid (1) and polyamic acid (2) include 4,4′-diaminodiphenyl ether, 3,4′-diaminodiphenyl ether, 4,4′-diaminophenylmethane, 3,3′-dimethyl-4,4′-diaminodiphenylmethane, 4,4′-diaminodiphenylsulfone, 4,4′-di(m-aminophenoxy)diphenylsulfone, 4,4′-diaminodiphenylsulfide, 1,4-diaminobenzene, 2,5-diaminotoluene, isophoronediamine, 4-(2-aminophenoxy)-1,3-diaminobenzene, 4-(4-aminophenoxy)-1,3-diaminobenzene, 2-amino-4-(4-aminophenyl)thiazole, 2-amino-4-phenyl-5-(4-aminophenyl)thiazole, benzidine, 3,3′,5,5′-tetramethylbenzidine, octafluorobenzidine, o-tolidine, m-tolidine, p-phenylenediamine, m-phenylenediamine, 1,2-bis(anilino)ethane, 2,2-bis(p-aminophenyl)propane, 2,2-bis(p-aminophenyl) hexafluoropropane, 2,6-diaminonaphthalene, diaminobenzotrifluoride, 1,4-bis(p-aminophenoxy)benzene, 4,4′-bis(p-aminophenoxy)biphenyl, diaminoanthraquinone, 1,3-bis(anilino)hexafluoropropane, 1,4-bis(anilino)octafluoropropane, and 2,2-bis[4-(p-aminophenoxy)phenyl]hexafluoropropane. Among these diamine compounds, p-phenylenediamine is effective for lowering the coefficient of thermal expansion; therefore, it is preferable that the diamine compounds contained in polyamic acid (2) have a p-phenylenediamine content of about 60 to 100 mol %.

The production of polyamic acid (1), which is a material for component (a), is conducted in an organic solvent that can dissolve polyamic acid (1) and an epoxy-containing alkoxysilane partial condensate described later. It is preferable that polyamic acid (1) be produced to have a polyimide-conversion solid residue of 5 to 60%. Here, the polyimide-conversion solid residue indicates the percentage by weight of polyimide relative to the polyamic acid solution when polyamic acid (1) is completely cured into polyimide. When the polyimide-conversion solid residue is less than 5%, the production cost of the polyamic acid solution becomes undesirably high. However, when it exceeds 60%, the polyamic acid solution becomes highly viscous at room temperature, and its handling tends to be difficult. Examples of usable organic solvents include dimethylsulfoxide, diethylsulfoxide, N,N-dimethylformamide, N,N-diethylformamide, N,N-dimethylacetamide, N,N-diethylacetamide, N-methyl-2-pyrrolidone, N-vinyl-2-pyrrolidone, phenol, o-, m-, or p-cresol, xylenol, halogenated phenol, catechol, hexamethylphosphoramide, γ-butyrolactone and like organic polar solvents. It is preferable that these organic polar solvents be used singly or in the form of a mixture. Furthermore, xylene, toluene and like aromatic hydrocarbons may be used in combination with the aforementioned polar solvents. Among these, dimethylsulfoxide, diethylsulfoxide, N,N-dimethylformamide, N,N-diethylformamide, N,N-dimethylacetamide, N,N-diethylacetamide, N-methyl-2-pyrrolidone, and N-vinyl-2-pyrrolidone are preferably used singly or in the form of a mixture.

The temperature of reaction of tetracarboxylic dianhydride with a diamine compound is not particularly limited as long as an amic acid group can remain therein, and preferably adjusted to about -20 to 80° C. When the reaction temperature is less than −20° C., the reaction speed becomes slow. This undesirably lengthens the time necessary for production, and is thus uneconomical. When the reaction temperature exceeds 80° C., an increased proportion of the amic acid group in the polyamic acid is subjected to ring closure to form an imide group. This tends to reduce the reactive sites with the epoxy-containing alkoxysilane partial condensate, and is thus undesirable.

The epoxy-containing alkoxysilane partial condensate used for the preparation of component (a) can be obtained, for example, from a dealcoholization reaction of an epoxy compound having one hydroxyl group per molecule with an alkoxysilane partial condensate. The number of epoxy groups of the epoxy compound is not particularly limited as long as the epoxy compound contains one hydroxyl group per molecule. Epoxy compounds having a smaller molecular weight exhibit higher compatibility with the alkoxysilane partial condensate, and provide higher heat resistance and adhesion. Therefore, an epoxy compound having a carbon number of 15 or less is preferably used. In particular, glycidol, epoxy alcohol, and the like, are preferably used. As glycidol, EPIOL OH (tradename, produced by NOF CORPORATION) and the like may be used. As an epoxy alcohol, EOA (tradename, produced by Kuraray Co., Ltd.) and the like may be used.

One example of an alkoxysilane partial condensate can be obtained by hydrolyzing the hydrolyzable alkoxysilane monomer represented by Formula (2) below:

R¹ₘSi(OR²)₍₄₋ₘ₎ (2)

wherein R¹ is an alkyl group having 8 or less carbons or an aryl group, R² is a lower alkyl group having 4 or less carbons, and m is an integer of 0 or 1, in the presence of acid or a base catalyst, and water, and then partially condensing the result.

Specific examples of hydrolyzable alkoxysilane monomers that are constituent materials for the alkoxysilane partial condensate include tetramethoxysilane, tetraethoxysilane, tetrapropoxysilane, tetraisopropoxysilane and like tetraalkoxysilane compounds; and methyltrimethoxysilane, methyltriethoxysilane, methyltripropoxysilane, methyltributoxysilane, ethyltrimethoxysilane, ethyltriethoxysilane, n-propyltrimethoxysilane, n-propyltriethoxysilane, isopropyltrimethoxysilane, isopropyltriethoxysilane and like trialkoxysilane compounds. Among these, an alkoxysilane partial condensate obtained using 70 mol % or more of tetramethoxysilane or methyltrimethoxysilane is particularly preferable as such an alkoxysilane partial condensate has a high reactivity with an epoxy compound containing one hydroxyl group per molecule.

Any alkoxysilane partial condensates exemplified above can be used without any particular limitation. When two or more of them are used in a mixture, it is preferable that the mixture contain 70 wt % or more tetramethoxysilane partial condensate or methyltrimethoxysilane partial condensate per total amount of alkoxysilane partial condensate. The number average molecular weight of the alkoxysilane partial condensate is preferably about 230 to 2,000, and the average number of silicon atoms per molecule is preferably about 2 to 11.

The epoxy-containing alkoxysilane partial condensate can be obtained by subjecting an epoxy compound containing one hydroxyl group per molecule and an alkoxysilane partial condensate to a dealcoholization reaction. The ratio of the epoxy compound to the alkoxysilane partial condensate is not particularly limited as long it allows the alkoxy group to substantially remain. For example, an epoxy-containing alkoxysilane partial condensate and an epoxy compound containing one hydroxyl group per molecule can be reacted in such ratio that the hydroxyl equivalent weight of epoxy compound containing one hydroxyl group per molecule/alkoxy equivalent weight of alkoxysilane partial condensate=0.01/1 to 0.3/1. More specifically, it is preferable that an epoxy-containing alkoxysilane partial condensate and an epoxy compound containing one hydroxyl group per molecule be subjected to a dealcoholization reaction in such a ratio that 0.01 to 0.3 hydroxyl equivalent weight of epoxy compound containing one hydroxyl group per molecule is used per one alkoxy equivalent weight of epoxy-containing alkoxysilane partial condensate. When the above ratio becomes unduly small, the proportion of alkoxysilane partial condensate that is not epoxy modified increases. This tends to make the block copolymerized polyimide/silica hybrid film opaque; therefore, it is preferable that the above ratio be 0.03/1 or more.

The reaction of an alkoxysilane partial condensate with an epoxy compound containing one hydroxyl group per molecule is, for example, as explained below. The components mentioned above are prepared and heated, and the dealcoholization reaction is conducted while distilling off the alcohol generated. The reaction temperature is about 50 to 150° C., and preferably 70 to 110° C. The total reaction time is about 1 to 15 hours.

Component (a) can be obtained by reacting polyamic acid (1) with the epoxy-containing alkoxysilane partial condensate.

The ratio of polyamic acid (1) to the epoxy-containing alkoxysilane partial condensate is not particularly limited, and it is preferable that the ratio (epoxy equivalent weight of epoxy-containing alkoxysilane partial condensate/the number of moles of tetracarboxylic dianhydride used in polyamic acid (1)) fall within the range of 0.01 to 0.6. More specifically, these compounds are used in such a proportion that 0.01 to 0.6 mole of epoxy group in the partial condensate is contained per mole of tetracarboxylic dianhydride. If the proportion of the epoxy group in the partial condensate is less than 0.01 mole, it is difficult to achieve the effect of the present invention, but if it exceeds 0.6 mole, the resulting polyimide/silica hybrid film tends to become opaque and is thus not preferable.

Component (b) can be obtained by reacting component (a) with polyamic acid (2), which is produced by a reaction of tetracarboxylic dianhydride with a diamine compound. Polyamic acid (2) to be reacted with component (a) may be prepared in the following manner. That is, tetracarboxylic dianhydride and a diamine compound are reacted to prepare polyamic acid (2) in advance, and the resulting polyamic acid (2) is mixed with component (a), or the tetracarboxylic dianhydride and diamine compound are added to component (a) to form polyamic acid (2) in the reaction system. Note that it is preferable that the tetracarboxylic dianhydride and diamine compound used in the preparation of polyamic acid (2) are different from those used in the preparation of polyamic acid (1). The reaction conditions for obtaining component (b) may be the same as those for obtaining component (a). The molecular weight of component (b) is not particularly limited and the number average molecular weight thereof (a polystyrene conversion value using gel permeation chromatography) is preferably about 10,000 to 1,000,000.

As the method for producing polyimide film (1) from component (b), known methods disclosed in, such as Japanese Unexamined Patent Publication No. 1993-70590, Japanese Unexamined Patent Publication No. 2000-119419, Japanese Unexamined Patent Publication No. 2007-56198, and Japanese Unexamined Patent Publication No. 2005-68408, can be employed. In order to obtain satisfactory productivity and low thermal expansion, a curing method using a catalyst is preferred. More specifically, for example, as disclosed in Japanese Unexamined Patent Publication No. 1993-70590, an alkoxy-containing silane modified block copolymerized polyamic acid (b) or its solution containing more than a stoichiometric amount of a dehydrating agent and a catalytic amount of tertiary amine is cast or applied to an endless belt to form a film, and the resulting film is dried in the temperature range from 150° C. or less for about 5 to 90 minutes, thereby obtaining a polyamic acid film having self-supporting properties. The thus obtained polyamic acid film is peeled off from the support with its ends being fixed, and gradually heated to about 100 to 500° C. for imidization. After cooling, the resulting film is removed from a drum or endless belt to obtain the polyimide film of the present invention. Examples of dehydrating agents include acetic anhydride and like aliphatic acid anhydrides, and benzoic anhydride and like aromatic acid anhydrides. Furthermore, examples of catalysts include triethylamine and like aliphatic tertiary amine compounds; dimethylaniline and like aromatic tertiary amine compounds; and pyridine, picoline, isoquinoline and like heterocyclic tertiary amine compounds.

The thickness of the polyimide film (1) thus obtained is not particularly limited and is suitably selected depending on the voltage of the circuit and the insulation performance and/or dynamic strength of the polyimide film (1). In view of the ease of production of polyimide film (1) and the working efficiency in the production of the multilayer printed board, the thickness of polyimide film (1) is preferably about 5 to 50 μm. If necessary, before performing electroless nickel plating, a step of forming a through hole and/or nonthrough hole in the polyimide film (1) may be added. When a through hole and/or nonthrough hole is provided, the formation thereof is preferably conducted before performing the electroless nickel plating. This allows the inner wall of the through hole and/or nonthrough hole to be covered with electroless nickel coat, simplifying the following process.

A polyimide film provided with a nickel plating layer is produced by subjecting the polyimide film (1) thus obtained to at least electroless nickel plating (first step).

The electroless nickel plating is generally performed in the following manner. First, a surface treatment step (A) (hereunder referred to as “step (A)”), a catalyst imparting step (B) (hereunder referred to as “step (B)”), a catalytic activation step (C) (hereunder referred to as “step (C)”) and like pretreatment before performing the electroless nickel plating are applied to polyimide film (1), and then an electroless nickel plating step (D) (hereunder referred to as “step (D)”) is performed.

Conditions for step (A) are not particularly limited and those for conventionally known alkaline surface treatment can be employed. Examples of alkaline surface treatment liquids include a sodium hydroxide aqueous solution, a potassium hydroxide aqueous solution, aqueous ammonia, and other organic amine compounds. A plurality of alkaline surface treatment liquids may be used in combination. As the alkaline surface treatment condition, for example, the use of SLP-100 Precondition (produced by Okuno Chemical Industries Co., Ltd.) is particularly preferable.

Conditions for step (B) are not particularly limited and those for a conventionally known catalyst imparting step for electroless nickel plating can be employed. Examples of the treatment liquid used in step (B) include an alkaline palladium catalyst-imparting liquid, an acidic palladium catalyst-imparting liquid, a platinum catalyst-imparting liquid, a nickel catalyst-imparting liquid, and other catalyst-imparting liquids for use in electroless nickel plating. A plurality of catalyst-imparting liquids for use in electroless nickel plating may be used in combination. As the catalyst-imparting liquid for use in electroless nickel plating, for example, SLP-400 Catalyst (produced by Okuno Chemical Industries Co., Ltd.) is particularly preferable.

Step (C) of the present invention is not particularly limited as long as it can activate the catalyst that was supported on polyimide film (1) in step (B) and a conventionally known one can be employed without any limitation. As the catalytic activation condition for use in the electroless nickel plating, the use of, for example, SLP-500 Accelerator (produced by Okuno Chemical Industries Co., Ltd.) is particularly preferable.

In step (D) of the present invention, a conventionally known electroless nickel plating liquid can be used without any limitation. Examples of the electroless nickel plating liquid include an electroless nickel-boron plating liquid, a low-phosphorus electroless nickel plating liquid, a mid-phosphorus electroless nickel plating liquid, and a high-phosphorus electroless nickel plating liquid. From the viewpoint of adhesion to polyimide film (1) and a selective etching property, the use of a mid-phosphorus electroless nickel plating liquid is preferred. As the mid-phosphorus electroless nickel plating liquid, for example, SLP-600 Nickel (produced by Okuno Chemical Industries Co., Ltd.) is particularly preferable.

Each of the treatment liquids used in steps (A) to (D) of the electroless nickel plating described above must have high adhesion to polyimide film (1); therefore, the use of the liquids mentioned above is preferable.

A copper plating layer may be formed on the electroless nickel plating layer insofar as it does not adversely affect the effect of the invention. By providing a copper plating layer on the nickel plating layer, the electroless copper plating layer may be used as an antioxidant layer of the electroless nickel plating layer.

In the present invention, the film thickness of the electroless nickel plating layer is 0.03 to 0.3 μm, and preferably 0.1 to 0.3 μm. When the film thickness of the electroless nickel plating layer is less than 0.03 μm, satisfactory adhesion cannot be attained. When the film thickness exceeds 0.3 μm, side etching occurs when selective etching is performed on the electroless nickel plating layer, and is thus not preferable.

A dry film resist layer is disposed on the polyimide film provided with the nickel plating layer obtained in the first step, followed by exposure and development to form a resist layer for pattern electrolytic copper plating (second step).

As the dry film resist used in the present invention, conventionally known ones can be used without limitation as long as they have satisfactory adhesion to the electroless nickel plating layer or the electroless copper plating layer, and exhibit an excellent ability to develop fine circuits. As the dry film resist, for example, ALPHO NIT4015 (produced by Nichigo-Morton Co., Ltd.) and Etertec HP3510 (produced by Eternal Chemical Co., Ltd.) are preferably used.

Copper plating is performed on the polyimide film provided with a resist layer for pattern electrolytic copper plating that was obtained in the second step to form an electrically conductive layer into a pattern (third step). After removing the resist layer for pattern electrolytic copper plating, the electroless nickel plating layer in the region other than the electrolytic copper plating layer is subjected to selective etching (fourth step), thereby obtaining the flexible circuit board of the present invention.

The conditions for each of the second to fourth steps may be the same as known conditions generally employed in a semi-additive process. The type of resist used in the semi-additive process, conditions for photography, conditions for electrolytic copper plating, conditions for resist layer removal and the like are not particularly limited, and conventionally known materials and methods can be employed.

The resist stripping solution used for removing the resist layer for pattern electrolytic copper plating is not particularly limited as long as it can remove the resist layer for pattern electrolytic copper plating, and known ones can be used. However, it is preferable to use a resist stripping solution that achieves quick removal of the resist and that peels the resist into small pieces. As the resist stripping solution, for example, OPC Persoli-312 (produced by Okuno Chemical Industries Co., Ltd.) is particularly preferable.

The etching solution for selectively etching the pattern electroless nickel plating layer in the region other than the electrolytic copper plating layer is not particularly limited as long as it can selectively etch the electroless nickel plating layer, and known ones can be used. It is preferable to use an etching solution that can remove the electroless nickel plating layer by dissolving and that has a low etching rate to the electrolytic copper plating layer. More specifically, when an etching solution having an etching rate to an electroless nickel plating layer of 1.0 μm/min or higher, and an etching rate to copper of 0.2 μm/min or lower, is used for the selective etching, only the nickel plating can be preferentially removed and the copper plating can be selectively retained. This makes it possible to obtain a material for flexible circuit boards having an excellent selective etching property. According to the present invention, the width and height of the patterned copper circuit formed by performing electrolytic copper plating can be made to meet fine pitch requirements, i.e., a width of about 4 to 18 μm and a height of about 2 to 20 μm.

After etching, the laminated substrate is preferably washed with an acidic aqueous solution or water in order to remove the etching solution. The patterned electrically conductive metal layer thus obtained has a satisfactory thickness and is formed in accordance with a high-resolution pattern. The method for producing the flexible circuit board of the present invention allows a high-definition electrically conductive circuit to be formed by a simple method; therefore, its range of application is very wide.

### EXAMPLES

Hereinafter, the present invention is described in detail with reference to Examples and Comparative Examples; however, the present invention is not limited to these examples.

### Example 1 (Sample for Adhesive Strength Measurement)

Using a polyimide/silica hybrid film (produced by Arakawa Chemical Industries, Ltd.; tradename: Pomiran T25; mol % of p-phenylenediamine in diamine component=80%; coefficient of thermal expansion from 100 to 200° C.=4 ppm/° C.; film thickness: 25 μm) and SLP Process (produced by Okuno Chemical Industries Co., Ltd.), a polyimide film provided with an electroless nickel plating layer (electroless nickel plating layer thickness: 0.1 μm) was produced. Dry film resist NIT4015 (produced by Nichigo-Morton Co., Ltd.) was adhered to the nickel plating layer, and a resist layer for pattern electrolytic copper plating with L/S=1/1 mm was formed under ordinary conditions. Thereafter, electrolytic copper plating was preformed using Top Lucina SF (produced by Okuno Chemical Industries Co., Ltd.) to form an electrically conductive layer into a pattern (conductive layer thickness: 9 μm). After removing the resist layer for electrolytic copper plating, the electroless nickel plating layer in the region other than the electrolytic copper plating layer was subjected to selective etching using Toplip NIP (produced by Okuno Chemical Industries Co., Ltd.) to obtain a flexible circuit board.

### Example 2 (Sample for Adhesive Strength Measurement)

Using a polyimide/silica hybrid film (produced by Arakawa Chemical Industries, Ltd., tradename: Pomiran T25, mol % of p-phenylenediamine in diamine component=80%, coefficient of thermal expansion from 100 to 200° C.=4 ppm/° C., film thickness: 25 μm) and SLP Process (produced by Okuno Chemical Industries Co., Ltd.), a polyimide film provided with an electroless nickel plating layer (electroless nickel plating layer thickness: 0.3 μm) was produced. Dry film resist NIT4015 (produced by Nichigo-Morton Co., Ltd.) was adhered to the nickel plating layer, and a resist layer for pattern electrolytic copper plating with L/S=1/1 mm was formed under ordinary conditions. Thereafter, electrolytic copper plating was performed using Top Lucina SF (produced by Okuno Chemical Industries Co., Ltd.) to form an electrically conductive layer into a pattern (conductive layer thickness: 9 μm). After removing the resist layer for electrolytic copper plating, the electroless nickel plating layer in the region other than the electrolytic copper plating layer was subjected to selective etching using Toplip NIP (produced by Okuno Chemical Industries Co., Ltd.) to obtain a flexible circuit board.

### Comparative Example 1 (Sample for Adhesive Strength Measurement)

Using a commercially available polyimide film (produced by Du Pont-Toray Co., Ltd.; tradename: Kapton H; mol % of p-phenylenediamine in diamine component=0%; coefficient of thermal expansion from 100 to 200° C.=43 ppm/° C.; film thickness: 25 μm) and SLP Process (produced by Okuno Chemical Industries Co., Ltd.), a polyimide film provided with an electroless nickel plating layer (electroless nickel plating layer thickness: 0.3 μm) was produced. Dry film resist NIT4015 (produced by Nichigo-Morton Co., Ltd.) was adhered to the nickel plating layer, and a resist layer for pattern electrolytic copper plating with L/S=1/1 mm was formed under ordinary conditions. Thereafter, electrolytic copper plating was performed using Top Lucina SF (produced by Okuno Chemical Industries Co., Ltd.) to form an electrically conductive layer into a pattern (conductive layer thickness: 9 μm). After removing the resist layer for electrolytic copper plating, the electroless nickel plating layer in the region other than the electrolytic copper plating layer was subjected to selective etching using Toplip NIP (produced by Okuno Chemical Industries Co., Ltd.) to obtain a flexible circuit board.

### Example 3 (Fine Circuit Formation Evaluation)

Using a polyimide/silica hybrid film (produced by Arakawa Chemical Industries, Ltd.; tradename: Pomiran T25; mol % of p-phenylenediamine in diamine component=80%; coefficient of thermal expansion from 100 to 200° C.=4 ppm/° C.; film thickness: 25 μm) and SLP Process (produced by Okuno Chemical Industries Co., Ltd.), a polyimide film provided with an electroless nickel plating layer (electroless nickel plating layer thickness: 0.1 μm) was produced. Dry film resist NIT4015 (produced by Nichigo-Morton Co., Ltd.) was adhered to the nickel plating layer, and a resist layer for pattern electrolytic copper plating with L/S=10/10 μm was formed under ordinary conditions. Thereafter, electrolytic copper plating was performed using Top Lucina SF (produced by Okuno Chemical Industries Co., Ltd.) to form an electrically conductive layer into a pattern (conductive layer thickness: 9 μm). After removing the resist layer for electrolytic copper plating, the electroless nickel plating layer in the region other than the electrolytic copper plating layer was subjected to selective etching using Toplip NIP (produced by Okuno Chemical Industries Co., Ltd.) to obtain a flexible circuit board.

### Example 4 (Fine Circuit Formation Evaluation)

Using a polyimide/silica hybrid film (produced by Arakawa Chemical Industries, Ltd.; tradename: Pomiran T25; mol % of p-phenylenediamine in diamine component=80%; coefficient of thermal expansion from 100 to 200° C.=4 ppm/° C.; film thickness: 25 μm) and SLP Process (produced by Okuno Chemical Industries Co., Ltd.), a polyimide film provided with an electroless nickel plating layer (electroless nickel plating layer thickness: 0.3 μm) was produced. Dry film resist NIT4015 (produced by Nichigo-Morton Co., Ltd.) was adhered to the nickel plating layer, and a resist layer for pattern electrolytic copper plating with L/S=10/10 μm was formed under ordinary conditions. Thereafter, electrolytic copper plating was performed using Top Lucina SF (produced by Okuno Chemical Industries Co., Ltd.) to form an electrically conductive layer into a pattern (conductive layer thickness: 9 μm). After removing the resist layer for electrolytic copper plating, the electroless nickel plating layer in the region other than the electrolytic copper plating layer was subjected to selective etching using Toplip NIP (produced by Okuno Chemical Industries Co., Ltd.) to obtain a flexible circuit board.

### Comparative Example 2 (Fine Circuit Formation Evaluation)

Using a polyimide/silica hybrid film (produced by Arakawa Chemical Industries, Ltd.; tradename: Pomiran T25; mol % of p-phenylenediamine in diamine component=80%; coefficient of thermal expansion from 100 to 200° C.=4 ppm/° C.; film thickness: 25 μm) and SLP Process (produced by Okuno Chemical Industries Co., Ltd.), a polyimide film provided with an electroless nickel plating layer (electroless nickel plating layer thickness: 1.0 μm) was produced. Dry film resist NIT4015 (produced by Nichigo-Morton Co., Ltd.) was adhered to the nickel plating layer, and a resist layer for pattern electrolytic copper plating with L/S=10/10 μm was formed under ordinary conditions. Thereafter, electrolytic copper plating was performed using Top Lucina SF (produced by Okuno Chemical Industries Co., Ltd.) to form an electrically conductive layer into a pattern (conductive layer thickness: 9 μm). After removing the resist layer for electrolytic copper plating, the electroless nickel plating layer in the region other than the electrolytic copper plating layer was subjected to selective etching using Toplip NIP (produced by Okuno Chemical Industries Co., Ltd.) to obtain a flexible circuit board.

### Peel Strength of Conductive Layer: Adhesive Strength

An electrically conductive layer portion (3 mm in width) of each of the circuit boards obtained in Examples 1 and 2, and Comparative Example 1, was peeled at a peeling angle of 180° and a peeling rate of 50 mm/min, and the load when peeled was measured. Also, circuit boards obtained in the same manner were heated at 150° C. for 168 hours, and then the load when peeled was measured in the same manner. Table 1 shows the results.

Cross sections of fine circuits obtained in Examples 3 and 4, and Comparative Example 2, were cleaved using a cross-section polisher (produced by JEOL Co., Ltd.), and the formation conditions thereof were evaluated using a scanning electron microscope. Table 2 shows the results.

TABLE 1

| | Adhesive strength (N/cm) | |
|---|---|---|
| | Initial value | After heating at 150° C. |
| Example 1 | 7 | 4 |
| Example 2 | 9 | 7 |
| Comparative Example 1 | 3 | 0.5 |

TABLE 2

| | Cross sectional shape of conductive layer |
|---|---|
| Example 3 | Rectangular |
| Example 4 | Rectangular |
| Comparative Example 2 | Floating and peeling observed |

As is clear from the results of Comparative Example 1, when a polyimide film having a high thermal expansion coefficient was used, the resulting circuit board had very low circuit adhesiveness due to the unsatisfactory adhesive strength to the electroless nickel plating layer. As is clear from the results of Comparative Example 2, when the electroless nickel plating layer was thick, the nickel layer portion below the conductive layer was also undesirably etched, causing floating and peeling of the conductive layer. In contrast, as shown in Examples 1 and 2, when a polyimide film having a low thermal expansion coefficient was used, a high adhesive strength was attained even after heating. Furthermore, circuit boards having excellent fine-circuit formation were obtained in Examples 3 and 4.

1-2. (canceled)

3. A process for obtaining a flexible circuit board, the flexible circuit board having a wiring pattern formed on a nickel plating layer of a polyimide film provided with a nickel plating layer that is obtained by laminating at least a nickel plating layer on a polyimide film, the polyimide film having a coefficient of thermal expansion of 0 to 8 ppm/° C. in the temperature range from 100 to 200° C., and the nickel plating layer having a thickness of 0.03 to 0.3 μm, the process comprising:
a first step of subjecting polyimide film (1) having a coefficient of thermal expansion of 0 to 8 ppm/° C. in the temperature range from 100 to 200° C. to at least electroless nickel plating to form a polyimide film provided with a nickel plating layer, wherein the nickel plating layer has a thickness of 0.03 to 0.3 μm,
a second step of forming a resist layer for pattern electrolytic copper plating by disposing a dry film resist layer on the polyimide film provided with the nickel plating layer obtained in the first step, and performing exposure and development,
a third step of forming an electrically conductive layer into a pattern by performing electrolytic copper plating on the polyimide film provided with a resist layer for pattern electrolytic copper plating obtained, and
a fourth step of selectively etching, after removing the resist layer for pattern electrolytic copper plating, the electroless nickel plating layer in the portion where the electrolytic copper plating layer is not provided.

4. A method for producing a flexible circuit board, the flexible circuit board having a wiring pattern formed on a nickel plating layer of a polyimide film provided with a nickel plating layer that is obtained by laminating at least a nickel plating layer on a polyimide film, the polyimide film having a coefficient of thermal expansion of 0 to 8 ppm/° C. in the temperature range from 100 to 200° C., and the nickel plating layer having a thickness of 0.03 to 0.3 μm, the method comprising:
a first step of subjecting polyimide film (1) having a coefficient of thermal expansion of 0 to 8 ppm/° C. in the temperature range from 100 to 200° C. to at least electroless nickel plating to form a polyimide film provided with a nickel plating layer, wherein the nickel plating layer has a thickness of 0.03 to 0.3 μm,
a second step of forming a resist layer for pattern electrolytic copper plating by disposing a dry film resist layer on the polyimide film provided with the nickel plating layer obtained in the first step, and performing exposure and development,
a third step of forming an electrically conductive layer into a pattern by performing electrolytic copper plating on the polyimide film provided with a resist layer for pattern electrolytic copper plating obtained, and
a fourth step of selectively etching, after removing the resist layer for pattern electrolytic copper plating, the electroless nickel plating layer in the portion where the electrolytic copper plating layer is not provided.

5. The method for producing a flexible circuit board according to claim 4, which further comprises forming a through hole and/or nonthrough hole in the polyimide film (1) before performing the electroless nickel plating in the first step.

6. The method for producing a flexible circuit board according to claim 4, wherein the polyimide film (1) is a block copolymerized polyimide/silica hybrid film obtained by heat curing an alkoxy-containing silane modified block copolymerized polyamic acid (b).

7. The method for producing a flexible circuit board according to claim 4, wherein, in the second step, the resist layer for pattern electrolytic copper plating is formed using a dry film resist, and, in the third step, the patterned copper circuit that is formed by electrolytic copper plating has a width of 4 to 18 μm.

8. The method for producing a flexible circuit board according to claim 4, wherein, in the second step, the resist layer for pattern electrolytic copper plating is formed using a dry film resist, and, in the third step, the patterned copper circuit that is formed by electrolytic copper plating has a height of 2 to 20 μm.

9. The method for producing a flexible circuit board according to claim 4, wherein a selective etching solution having an etching rate for copper of 0.2 μm/min or lower and an etching rate for electroless nickel plating layer of 1.0 μm/min or higher is used in the selective etching performed in the fourth step.

10. The method for producing the flexible circuit board according to claim 4, wherein an electroless copper plating layer is further formed on the electroless nickel plating layer in the first step.
